(19) United States
(12) Patent Application Publication
(10) Pub. No.: US 2016/0111305 A1
(43) Pub. Date: Apr. 21, 2016

(54) APPARATUS FOR ADJUSTABLE LIGHT SOURCE

(71) Applicant: Applied Materials, Inc., Santa Clara, CA (US)

(72) Inventors: Navjot Kumar, Bangalore (IN); Nyi O. MYO, San Jose, CA (US); Schubert S. CHU, San Francisco, CA (US); Kamesh GIRIDHAR, Bangalore (IN); Palamurali GAJENDRA, Bangalore (IN)

(21) Appl. No.: 14/864,261

(22) Filed: Sep. 24, 2015

Related U.S. Application Data
(60) Provisional application No. 62/116,990, filed on Feb. 17, 2015.
(60) Provisional application No. 62/066,542, filed on Oct. 21, 2014.

(51) Int. Cl. H01L 21/67; H05B 3/00

(52) U.S. Cl. CPC H01L 21/67115; H05B 3/0047

(57) ABSTRACT

Apparatus for adjusting the position of lamp modules of a processing chamber are disclosed herein. Implementations generally include a process chamber comprising an enclosure defining an internal volume, a substrate support disposed in the internal volume of the process chamber, and a plurality of adjustable lamp modules. Each adjustable lamp module can include a radiation source, a lamp connector in connection with the radiation source, an adjustable mounting bracket connected to the lamp connector, the adjustable mounting bracket being pivotably connected to the process chamber; and a adjustable force device mounted in connection with the adjustable mounting bracket.

### CROSS-REFERENCE TO RELATED APPLICATIONS

This application claims priority to U.S. Provisional Patent Application Ser. No. 62/066,542 (Attorney Docket No. 022162/USAL), filed Oct. 21, 2014, and U.S. Provisional Patent Application Ser. No. 62/116,990 (Attorney Docket No. 022162/USAL02), filed Feb. 17, 2015, which are incorporated by reference herein.

### BACKGROUND

1. Field

Implementations of the present disclosure generally relate to an adjustable light source. More specifically, implementations described herein generally relate to apparatus, systems and methods for controlling the position of a light source in a process chamber.

2. Description of the Related Art

Several applications that involve the thermal processing of substrates such as semiconductor wafers and other materials involve the process steps of rapidly heating and cooling a substrate. One example of such processing is rapid thermal processing (RTP), which is used for a number of semiconductor fabrication processes.

In rapid thermal processing (RTP), heat energy radiates from radiation sources into the process chamber and onto a semiconductor substrate in the processing chamber. In this manner, the substrate is heated to a processing temperature. During semiconductor processing operations, the radiation sources may operate at elevated temperatures. Not all of the radiant energy provided by the radiation sources end up actually heating the wafer. Some of the radiant energy, for example energy emitted in all directions from a point source, is absorbed by chamber components, especially the reflective components in the radiation field.

In addition, in the semiconductor industry, it is often desirable to maintain temperature uniformity in the substrate during thermal processing. Temperature uniformity enables uniform processing of the substrate (e.g. layer thickness, resistivity, etch depth) for thermal processes such as film deposition, oxide growth, and etching. Furthermore, temperature uniformity helps prevent thermal stress-induced substrate damage such as warpage, defect generation, and substrate slip.

Typically the individual radiation sources in chambers may be horizontal during first installation with the emitter of each source oriented along a plane defined by the substrate. Over time, the emitters may sag due to gravitational forces, thermal cycling, or other reasons. This sag can cause a change in distance between emitter and substrate, which can results in temperature variation in the substrate.

Accordingly, what is needed in the art is apparatus and methods for controlling emitter position over time.

### SUMMARY

Implementations disclosed herein include a method of repositioning a radiation source. In one implementation, an apparatus for processing a semiconductor substrate can include a process chamber comprising an enclosure defining an internal volume; a substrate support disposed in the internal volume of the process chamber; and a plurality of radiation emitters; an adjustable bracket comprising a base connected to at least one of the radiation emitters and an adjustable bracket connected to the base, the adjustable bracket being pivotably connected to the process chamber; and an adjuster connected with the adjustable bracket.

In another implementation, a system for processing a substrate can include a process chamber comprising an enclosure, the enclosure having an upper portion and a lower portion defining a processing region; a substrate support disposed in the processing region; a plurality of lamp modules connected to the upper portion for delivering radiation to the processing region; and an adjustable bracket connected to at least one of the lamp modules; and an adjuster connected with the adjustable bracket, the adjuster providing provide a force for pivoting the adjustable bracket.

In another implementation, an apparatus for processing a semiconductor substrate can include a plurality of radiation modules positioned in an upper portion of a process chamber, each radiation module comprising: a radiation source; a base connected to the radiation source; an adjustable bracket connected to the radiation source, the adjustable bracket comprising: a base connected to the radiation source; a first member comprising a first arm and a second arm, wherein the first arm is connected to the base; a second member connected to the first member by a pivot; and a spring connected between the second arm of the first member and the second member; and an adjuster connected with the first member to provide a pivoting force to the first member.

### BRIEF DESCRIPTION OF THE DRAWINGS

So that the manner in which the above recited features of the present disclosure can be understood in detail, a more particular description of the disclosure, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 is a schematic cross-sectional view of one implementation of a processing chamber.

FIG. 2 is a side view of a radiation module with an adjustable orientation according to one implementation.

FIG. 3 is a side view of a radiation module with an adjustable orientation according to another implementation.

FIG. 4A is a side view of a radiation module with an adjustable orientation according to another implementation.

FIG. 4B is a detailed view of an adjuster of the radiation module of FIG. 4A, according to one implementation.

FIG. 5 is a side view of a radiation module with an adjustable position and an adjustable orientation, according to another implementation.

FIG. 6 is a side view of a radiation module with an adjustable position and an adjustable rotation, according to one implementation.

To facilitate understanding, identical reference numerals have been used, wherever possible, to designate identical elements that are common to the Figures. Additionally, elements of one implementation may be advantageously adapted for utilization in other implementations described herein.

### DETAILED DESCRIPTION

Implementations disclosed herein include apparatus and systems for positioning and orienting a radiation source in a thermal processing chamber. After hours of operation, the emitter in a radiation source may shift position, orientation or both. Disclosed here are various implementations of an adjustment apparatus that enables adjustment of the position and orientation of the radiation source to compensate for a shift in the emitter. The implementations of the apparatus and systems are more clearly described with reference to the figures below.

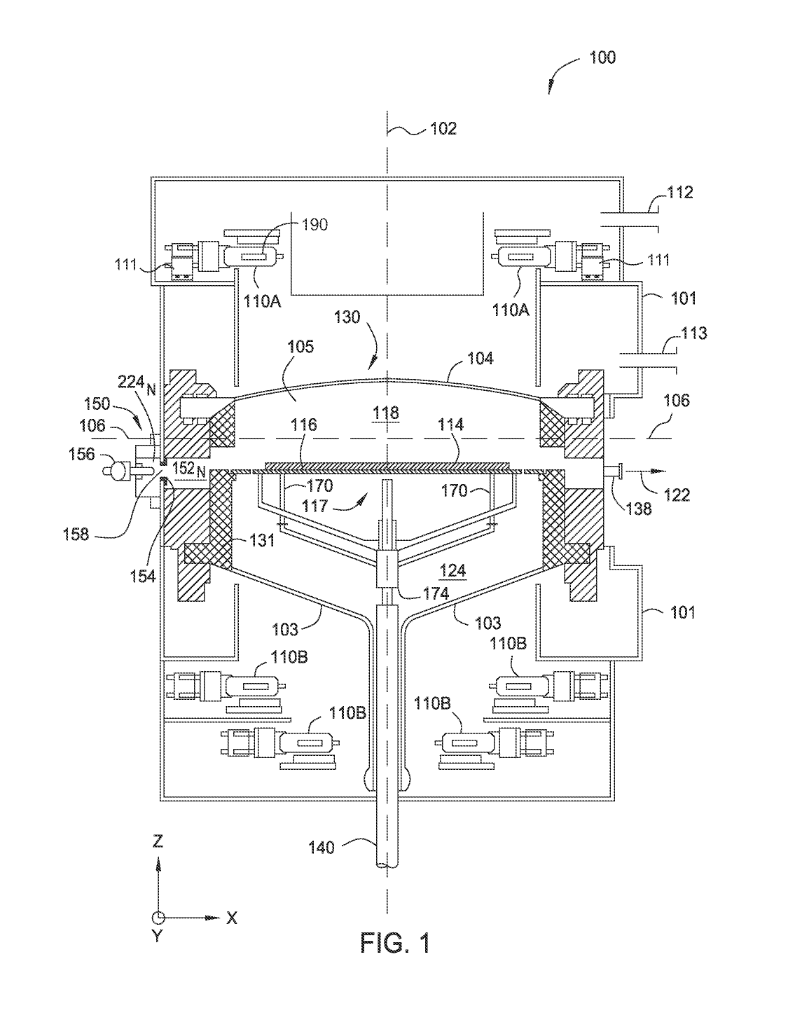

FIG. 1 is a schematic cross-sectional view of a process chamber 100 configured for epitaxial processing, which may be part of a CENTURA® integrated processing system available from Applied Materials, Inc., of Santa Clara, Calif. The process chamber 100 includes housing structure 101 made of a process resistant material, such as aluminum or stainless steel, for example 316L stainless steel. The housing structure 101 encloses various functioning elements of the process chamber 100, such as a enclosure 130, which includes an upper chamber 105, and a lower chamber 124, and which defines a processing volume. Reactive species are provided to the enclosure 130, which may be quartz, by a gas distribution assembly 150, and processing byproducts are removed from processing volume 118 by an port 138, which is typically in communication with a vacuum source (not shown).

A substrate support 117 is adapted to receive a substrate 114 that is transferred to the processing volume 118. The substrate support 117 may be made of a ceramic material or a graphite material coated with a silicon material, such as silicon carbide, or other process resistant material. Reactive species from precursor reactant materials are applied to the exposed surface of the substrate 114, and byproducts may be subsequently removed from the surface of the substrate 114. Heating of the substrate 114 and/or the processing volume 118 may be provided by radiation modules, such as upper lamp modules 110A and lower lamp modules 110B. Though described as upper and lower lamp module, this is not intended to be limiting. The implementations described herein are equally applicable to chambers in other orientations, such as vertical chambers. Additionally, emitters may be lamps with filaments or arrays of solid state emitters, such as LED's. To illustrate operation of the adjustment apparatus, lamp modules are used as exemplary radiation emitters. The substrate support 117 may rotate about a central axis 102 of the substrate support while moving in a direction parallel to the central axis 102 by displacement of support shaft 140. Lift pins 170 are provided that penetrate the surface 116 of the substrate support 117 and lift the substrate 114 above the substrate support 117 for transportation into and out of the processing chamber. The lift pins 170 are coupled to the support shaft 140 by a lift pin collar 174.

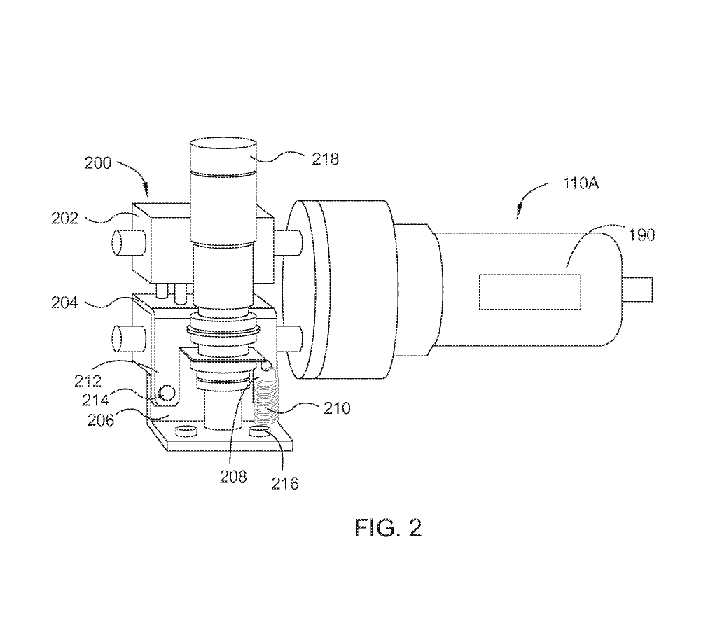

In one implementation, the upper lamp modules 110A and lower lamp modules 110B are infrared (IR) lamps. Each lamp typically includes a filament 190, which produces energy or radiation. The energy or radiation from upper lamp modules 110A travels through upper window 104 of upper chamber 105. Respectively, energy or radiation from lower lamp modules 110B travels through the lower portion 103 of lower chamber 124. Cooling gases for upper chamber 105, if needed, enter through a port 112 and exit through a port 113. Precursor reactant materials, as well as diluent, purge and vent gases for the chamber 100, enter through gas distribution assembly 150 and exit through port 138. The upper lamp modules 110A are may be held by an adjustable bracket 111. The adjustable bracket 111 can pivot with relation to the chamber such that the upper lamp modules 110A can change position within the upper chamber 105. Implementations of adjustable brackets 111 are explained in more detail with reference to FIGS. 2-4.

The radiation used to energize reactive species and assist in adsorption of reactants and desorption of process byproducts from the surface 116 of substrate 114 may range from about 0.8 μm to about 1.2 μm, for example, between about 0.95 μm to about 1.05 μm. Combinations of various wavelengths may be provided depending, for example, on the composition of the film which is being epitaxially grown. In another implementation, the lamp modules 110A and 110B may be ultraviolet (UV) light sources, for example Excimer lamps. In another implementation, UV light sources may be used in combination with IR light sources in one or both of the upper chamber 105 and lower chamber 124.

The component gases enter the processing volume 118 via gas distribution assembly 150 through port 158, which may have an inlet cap 154, and through passage 152N. The inlet cap 154 may be a nozzle in some implementations. The gas distribution assembly 150 may include a tubular heating element 156 disposed in a conduit 224N to heat the processes gases to a desired temperature before they enter the processing chamber. Gas flows from the gas distribution assembly 150 and exits through port 138 as shown at 122. Combinations of component gases, which are used to clean/passivate a substrate surface, or to form the silicon and/or germanium-containing film that is being epitaxially grown, are typically mixed prior to entry into the processing volume. The overall pressure in the processing volume 118 may be adjusted by a valve (not shown) on the port 138. At least a portion of the interior surface of the processing volume 118 is covered by a liner 131. In one implementation, the liner 131 comprises a quartz material that is opaque. In this manner, the chamber wall is insulated from the heat in the processing volume 118.

The temperature of surfaces in the processing volume 118 may be controlled within a temperature range of about 200° C. to about 600° C., or greater, by the flow of a cooling gas, which enters through a port 112 and exits through port 113, in combination with radiation from upper lamp modules 110A positioned above upper window 104. The temperature in the lower chamber 124 may be controlled within a temperature range of about 200° C. to about 600° C. or greater, by adjusting the speed of a blower unit which is not shown, and by radiation from the lower lamp modules 110B disposed below lower chamber 124. The pressure in the processing volume 118 may be between about 0.1 Torr to about 600 Torr, such as between about 5 Torr to about 30 Torr.

The temperature on a surface of the substrate 114 may be controlled by power adjustment to the lower lamp modules 110B in lower chamber 124, or by power adjustment to both the upper lamp modules 110A overlying upper chamber 105, and the lower lamp modules 110B in lower chamber 124. The power density in the processing volume 118 may be between about 40 W/cm² to about 400 W/cm², such as about 80 W/cm² to about 120 W/cm².

In one aspect, the gas distribution assembly 150 is disposed normal to, or in a radial direction 106 relative to, the central axis 102 of the chamber 100 or substrate 114. In this orientation, the gas distribution assembly 150 is adapted to flow process gases in a radial direction 106 across, or parallel to, a surface of the substrate 114. In one application, the process gases are preheated at the point of introduction to the chamber 100 to initiate preheating of the gases prior to introduction to the processing volume 118, and/or to break specific bonds in the gases. In this manner, surface reaction kinetics may be modified independently from the thermal temperature of the substrate 114.

FIG. 2 depicts the upper lamp module 110A with an adjustable bracket 200, according to an implementation. The adjustable bracket 200 includes a base 202 that connects to the upper lamp module 110A, a first member 204 and a second member 206. The base 202 can be composed of materials which are compatible with electrically conductive and radiation producing components. In one implementation, the base 202 is composed of a ceramic.

The base 202, which may be a lamp base, can be connected to the first member 204 and the second member 206. The first member 204 can be connected to the base 202. As used herein, “connected with” indicates that the connection between two objects may contain an intervening object whereas “connected to” indicates that the connection between two objects is direct. Also, the intervening object may be referred to as being “connected between” the two objects. The first member 204 can have one or more arms, shown here as a first arm 208 and a second arm 212. The one or more arms can connect the first member 204 with the second member 206 at one or more connection points. In this implementation, the first arm 208 is connected with the second member 206 by a spring 210, which may be a coil spring, a leaf spring, or any other type of spring. The second arm 212 is connected to the second member 206 by a pivot 214, shown here as a bolt. The second member 206 is connected to the chamber 100 by connectors 216. An adjuster 218, shown here as a micrometer, is connected with the first member 204 and is positioned between the first member 204 and the second member 206. In this implementation, the base of the adjuster 218 rests on a portion of the second member 206. However, it is not necessary that the adjuster 218 contact the second member 206.

In operation of a lamp implementation with a filament, the filament 190 of the upper lamp module 110A produces energy or radiation which is used in thermal processing of the substrate 114. After a certain number of cycles, the filament 190 may begin to change position and/or orientation, such as by sag toward the direction of gravitational force, as when the filament 190 sags toward the substrate 114. The position of an object is with consideration of a three dimensional space.

The changing of position and orientation of the filament 190 will affect the amount of radiation delivered through the upper window 104 of upper chamber 105 and thus to the substrate 114. The adjuster 218 can be adjusted to provide a first force against a wall, such as a portion of the second member 206, and against the first member 204. As force is applied from the adjuster 218, the first member 204 will pivot with relation to the second member 206 at the pivot 214. As the first member 204 pivots, the upper lamp module 110A and the filament 190 will be repositioned in a controlled fashion. The spring 210 provides force in the opposite direction to the force of the adjuster 218, such that the first member 204 can be repositioned both up and down based on the desires of the user. By being able to shift the position of the upper lamp module 110A, the effects of sagging at the filament 190 can be mitigated.

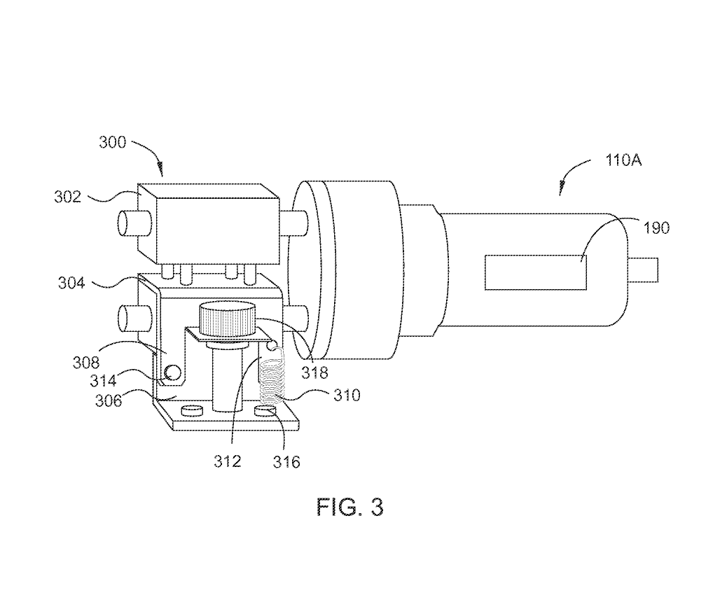

FIG. 3 depicts the upper lamp module 110A in connection with an adjustable bracket 300, according to another implementation. The adjustable bracket 300 includes a base 302 which is connected to the upper lamp module 110A. The base 302 can be composed of materials as descried with reference to the base 202 of FIG. 2.

The base 302 is connected to a first member 304 and a second member 306. The first member 304 can have a one or more arms, shown here as a first arm 308 and a second arm 312. In this implementation, the first arm 308 is connected with the second member 306 using a spring 310. The second arm 312 is connected to the second member 306 using a pivot 314, shown here as a bolt. The second member 306 is connected to the chamber 100 by connectors 316. In this implementation, an adjustment bolt 318 is connected with the first member 304 and is positioned between the first member 304 and the second member 306 with the base of the adjustment bolt 318 resting on a portion of the second member 306. The adjustment bolt 318 can be any threaded rod with a known pitch.

In operation, the filament 190 of the upper lamp module 110A produces energy or radiation which is used in thermal processing of the substrate 114. After a certain number of cycles, the filament 190 may begin to sag as described above with reference to FIG. 2. The adjustment bolt 318 can be adjusted to provide a first force against a wall, such as a portion of the second member 306, and against the first member 304. As force is applied from the adjustment bolt 318, the first member 304 will pivot with relation to the second member 306 at the pivot 314. As the first member 304 pivots, the upper lamp module 110A and the filament 190 will be repositioned in a controlled fashion. The spring 310 provides force in the opposite direction to the force of the adjustment bolt 318, such that the first member 304 can be repositioned both up and down based on the desires of the user.

Other adjusters may be used. In one example, an actuator may be used in place of the adjuster 218, the adjustment bolt 318, the spring 210, and/or the spring 310. The actuator may be remotely controlled, such that the user does not need to manually adjust the height of the upper lamp modules 110A. In one implementation, the actuator is controlled using a computer configured to perform said operations. In another implementation, a single device for providing a controlled directional force is used to apply force for a plurality of the upper lamp modules 110A.

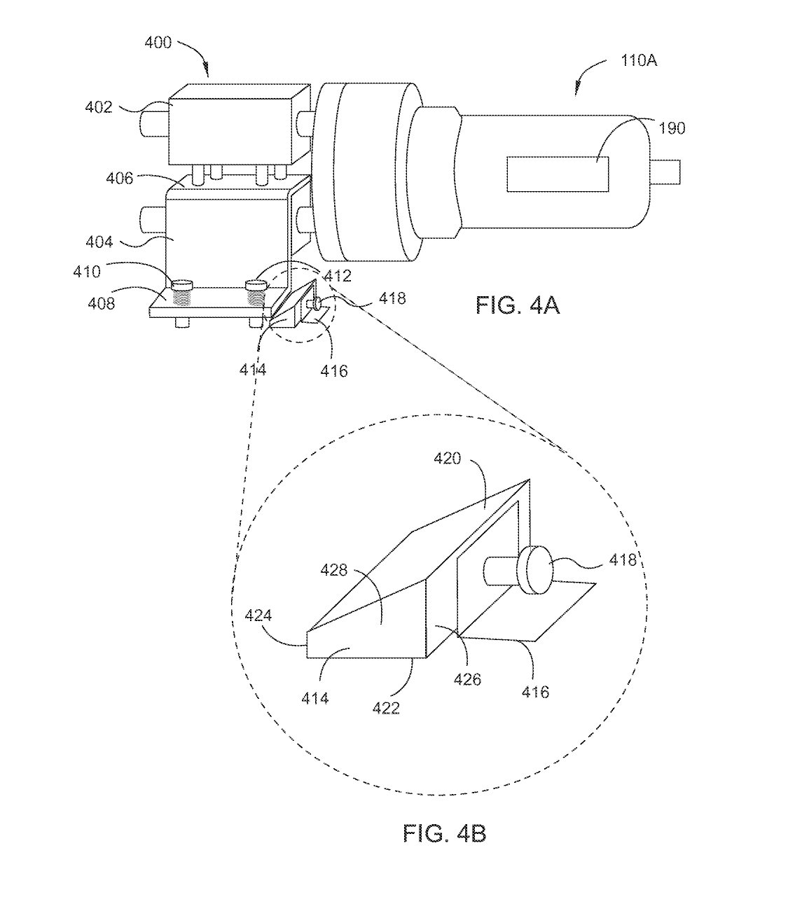

FIG. 4A depicts the upper lamp module 110A in connection with an adjustable bracket 400, according to another implementation. The adjustable bracket 400 includes a base 402 connected to the upper lamp module 110A. The base 402 can be composed of materials as descried with reference to the base 202 of FIG. 2.

The base 402 is connected to an adjustable bracket 404. The adjustable bracket 404 is shown here as a unibody design with a zigzagging configuration, thus creating two surfaces, an upper surface 406 and a lower surface 408. The upper surface 406 is connected to the base 402. The lower surface 408 connects with the chamber 100 using a plurality of spring-loaded bolts, depicted here as spring-loaded bolt 410 and spring-loaded bolt 412. The spring-loaded bolts 410 and 412 are elongated bolts with springs positioned between the head of the elongated bolt and a surface, shown here as the lower surface 408.

An adjustment wedge 414 can be positioned at an edge of the lower surface 408. FIG. 4B provides a more detailed view of the adjustment wedge 414, according to one implementation. The adjustment wedge 414 can have an angled wall 420, a supporting wall 422, a front wall 424, a back wall 426 and two side walls 428. The angled wall 420 forms an upper surface of the adjustment wedge 414, allowing for a reduced height between the back wall 426 and the front wall 424. The supporting wall 422 is substantially opposite the angled wall 420. The adjustment wedge 414 can move along a track (not shown), where the track is in connection with the supporting wall, 422, to provide precise movement. The back wall 426 is opposite to an adjustment support 416. In this implementation, the adjustment support 416 is depicted as being an L-shaped device. However, the shape of the adjustment support 416 is not intended to be limiting. The adjustment support 416 may have one or more adjustment bolts 418 formed through a wall in the direction of the adjustment wedge 414. The adjustment bolts 418 may be any threaded rod with a known pitch.

In operation, the filament 190 of the upper lamp module 110A produces energy or radiation which is used in thermal processing of the substrate 114. After a certain number of cycles, the filament 190 may begin to sag as described above with reference to FIG. 2. The adjustment bolt 418 can be adjusted to provide a first force against back wall 426 and against the adjustment support 416. As force is applied from the adjustment bolt 418, the adjustment wedge 414 will move or slide with relation to the adjustment support 416. The adjustment wedge 414 will then slide under the lower surface 408 of the base 402. The force form the adjustment wedge 414 will cause one or more of the spring-loaded bolts 410 and 412 to compress and causing the adjustable bracket 404 to pivot. The adjustable bracket 404 pivots about an axis perpendicular to a central axis of the upper lamp module 110A because the spring of the spring-loaded bolt 412 nearest the adjustment wedge 414 compresses more than springs of spring-loaded bolts 410 and 412 further from the adjustment wedge 414. As the adjustable bracket 404 pivots, the upper lamp module 110A and the filament 190 will be repositioned in a controlled fashion. The spring-loaded bolts 410 and 412 provide force in the opposite direction to the force of the adjustment wedge 414, such that the adjustable bracket 404 can be repositioned both up and down based on the desires of the user. The adjustment wedge 414 will be calibrated on all sides to ensure that precise tilt of the upper lamp module 110A is achieved. The adjustment wedge 414 can be mounted either on front side (as shown in FIG. 4A) or rear side of base 402.

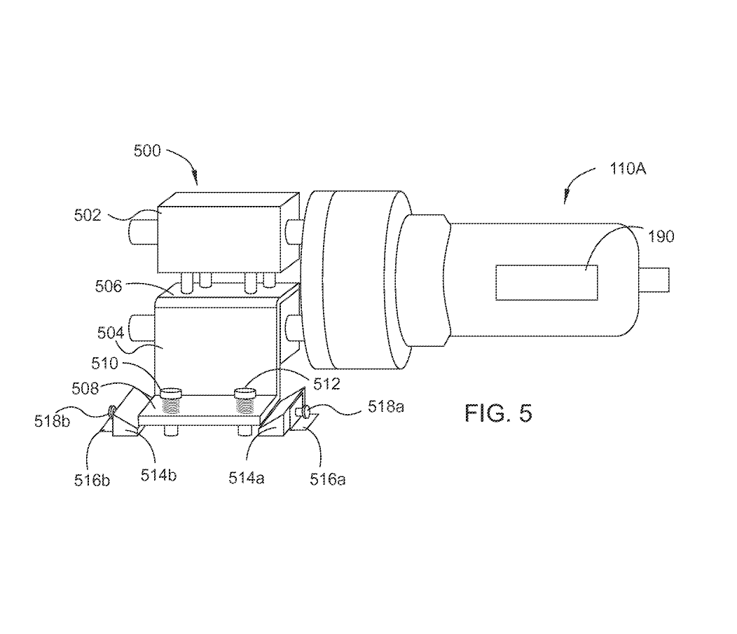

FIG. 5 depicts the upper lamp module 110A in connection with an adjustable bracket 500, according to another implementation. The adjustable bracket 500 includes a base 502 connected to the upper lamp module 110A. The base 502 can be composed of materials as descried with reference to the base 202 of FIG. 2.

The base 502 is connected to an adjustable bracket 504. The adjustable bracket 504 is shown here as a unibody design with a zigzagging configuration, thus creating two surfaces, an upper surface 506 and a lower surface 508. The upper surface 506 is connected to the base 502. The lower surface 508 connects with the chamber 100 using a plurality of spring-loaded bolts, depicted here as spring-loaded bolt 510 and spring-loaded bolt 512. The spring-loaded bolts 510 and 512 are elongated bolts with springs positioned between the head of the elongated bolt and a surface, shown here as the lower surface 508.

A plurality of adjustment wedges, shown here as adjustment wedges 514a and 514b, can be positioned at an edge of the lower surface 508. The adjustment wedges 514a and 514b have an angled wall, a supporting wall, a front wall, a rear wall and two side walls, shown and described with reference to FIG. 4B as angled wall 420, a supporting wall 422, a front wall 424, a back wall 426 and two side walls 428. The adjustment wedges 514a and 514b can move along a track (not shown), where the track is in connection with the supporting wall to provide precise movement. The back walls of adjustment wedges 514a and 514b are opposite to adjustment supports 516a and 516b. In this implementation, the adjustment supports 516a and 516b are depicted as being an L-shaped device. However, the shape of the adjustment supports 516a and 516b are not intended to be limiting. The adjustment supports 516a and 516b may have one or more adjustment bolts, shown here as adjustment bolts 518a and 518b, formed through a wall in the direction of the respective adjustment wedges 514a and 514b. The adjustment bolts 518a and 518b may be a threaded rod, such as a threaded rod with a known pitch.

In operation, the filament 190 of the upper lamp module 110A produces energy or radiation which is used in thermal processing of the substrate 114. After a certain number of cycles, the filament 190 may begin to sag as described above with reference to FIG. 2. The adjustment bolts 518a and 518b can be adjusted to provide a first force against the back wall and against the adjustment supports 516a and 516b. As force is applied from the adjustment bolt 518, the adjustment wedges 514a and 514b will move or slide with relation to the adjustment support 516. The adjustment wedges 514a and 514b will then slide under the lower surface 508 of the base 502. The force from each of the adjustment wedges 514a and 514b will cause one or more of the spring-loaded bolts 510 and 512 to compress and causing the adjustable bracket 504 to pivot or lift. In one implementation, the adjustable bracket 504 pivots about an axis perpendicular to a central axis of the upper lamp module 110A because the spring of the spring-loaded bolt 512 nearest the adjustment wedges 514a and 514b compresses more than springs of spring-loaded bolts 510 and 512 further from the adjustment wedges 514a and 514b. As the adjustable bracket 504 pivots, the upper lamp module 110A and the filament 190 will be repositioned in a controlled fashion. In another implementation, the adjustable bracket 504 of the upper lamp module 110A lifts to a second position while maintaining at least one of original orientation parameters (e.g., pitch, roll, yaw or combinations thereof) because the springs of the spring-loaded bolts 510 and 512 compress in a fashion as to maintain one or more of the orientation parameters above. As the adjustable bracket 504 pivots, the upper lamp module 110A and the filament 190 will be repositioned in a controlled fashion. The spring-loaded bolts 510 and 512 provide force in the opposite direction to the force of the adjustment wedges 514a and 514b, such that the adjustable bracket 504 can be repositioned both up and down based on the desires of the user. The adjustment wedges 514a and 514b will be calibrated on all sides to ensure that precise tilt of the upper lamp module 110A is achieved. Combinations of both position and orientation can be changed simultaneously in this implementation, such that the device is shifted in space and oriented at the new position.

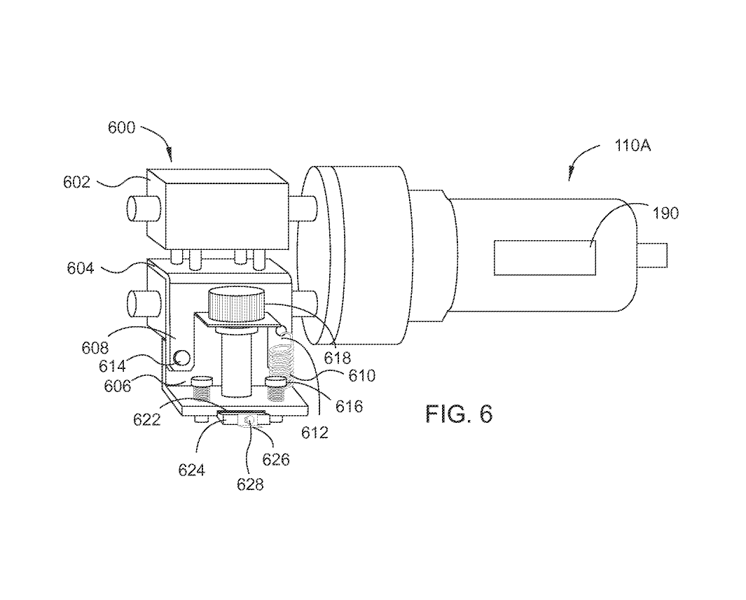

FIG. 6 depicts the upper lamp module 110A in connection with an adjustable bracket 600, according to another implementation. The adjustable bracket 600 includes a base 602 which is connected to the upper lamp module 110A. The base 602 can be composed of materials as descried with reference to the base 202 of FIG. 2.

The base 602 is connected to a first member 604 and a second member 606. The first member 604 can have a one or more arms, shown here as a first arm 608 and a second arm 612. In this implementation, the first arm 608 is connected with the second member 606 using a spring 610. The second arm 612 is connected to the second member 606 using a pivot 614, shown here as a bolt. The second member 606 is connected to the chamber 100 by connectors 616. Shown here, the connectors 616 are spring-loaded bolts. In this implementation, an adjustment bolt 618 is connected with the first member 604 and is positioned between the first member 604 and the second member 606 with the base of the adjustment bolt 618 resting on a portion of the second member 606. The adjustment bolt 618 can be any threaded rod, such as a threaded rod with a known pitch.

Further, the second member 606 can have a slit 622 to receive an adjustment wedge 624. The adjustment wedge 624 has an angled wall, a supporting wall, a front wall, a rear wall and two side walls, shown and described with reference to FIG. 4B as angled wall 420, a supporting wall 422, a front wall 424, a back wall 426 and two side walls 428. The adjustment wedge 624 can move along a track (not shown), where the track is in connection with the supporting wall to provide precise movement. The back walls of adjustment wedge 624 are opposite to an adjustment support 526. In this implementation, the adjustment support 626 is depicted as being an L-shaped device. However, the shape of the adjustment support 626 is not intended to be limiting. The adjustment support 626 may have one or more adjustment bolts, shown here as adjustment bolt 628, formed through a wall in the direction of the respective adjustment wedge 624. The adjustment bolt 628 may be a threaded rod, such as a threaded rod with a known pitch.

In operation, the filament 190 of the upper lamp module 110A produces energy or radiation which is used in thermal processing of the substrate 114. After a certain number of cycles, the filament 190 may begin to sag as described above with reference to FIG. 2. The adjustment bolt 618 can be adjusted to provide a first force against a wall, such as a portion of the second member 606, and against the first member 604. As force is applied from the adjustment bolt 618, the first member 604 will pivot with relation to the second member 606 at the pivot 614. As the first member 604 pivots, the upper lamp module 110A and the filament 190 will be repositioned in a controlled fashion. The spring 610 provides force in the opposite direction to the force of the adjustment bolt 618, such that the first member 604 can be repositioned both up and down based on the desires of the user. Simultaneously or independently form the adjustment bolt 618, the adjustment bolt 628 can be adjusted to provide a second force against the back wall and against the adjustment support 516. As force is applied from the adjustment bolt 628, the adjustment wedge 624 will move or slide with relation to the adjustment support 626. The adjustment wedge 624 will then slide under the slit 622. The force from the adjustment wedge 624 will cause one or more of the spring-loaded bolts 510 and 512 to tilt, compress or both, causing the first member 604 to pivot or lift.

Other adjusters may be used. In one example, an actuator may be used in place of the adjuster 218, the adjustment bolt 618, the spring 210, and/or the spring 610. The actuator may be remotely controlled, such that the user does not need to manually adjust the height of the upper lamp modules 110A. In one implementation, the actuator is controlled using a computer configured to perform said operations. In another implementation, a single device for providing a controlled directional force is used to apply force for a plurality of the upper lamp modules 110A.

The previously described implementations have many advantages. By being able to reposition the upper lamp modules, the lamp modules will need to be replaced less frequently. This allows for both cost savings and more precise thermal treatment of substrates over the life of the lamps. Further, though the implementations described herein are described with reference to the upper lamp module, it is understood that these implementations are equally applicable to the lower lamp module or other lamps which may be used within a processing chamber. The aforementioned advantages are illustrative and not limiting. It is not necessary for all implementations to have all the advantages.

While the foregoing is directed to implementations of the disclosed apparatus, methods and systems, other and further implementations of the disclosed apparatus, methods and systems may be devised without departing from the basic scope thereof, and the scope thereof is determined by the claims that follow.

What is claimed is:

1. An apparatus for processing a semiconductor substrate, comprising:
a process chamber comprising an enclosure defining an internal volume;
a substrate support disposed in the internal volume of the process chamber;
a plurality of radiation emitters;
an adjustable bracket comprising a base connected to at least one of the radiation emitters, the adjustable bracket being pivotably connected to the process chamber; and
an adjuster connected with the adjustable bracket.

2. The apparatus of claim 1, wherein the adjuster is a micrometer.

3. The apparatus of claim 1, wherein the adjustable bracket comprises a first member and a second member pivotably connected to the first member.

4. The apparatus of claim 3, wherein the first member comprises a first arm and a second arm.

5. The apparatus of claim 4, wherein the first arm is pivotably connected to the second member.

6. The apparatus of claim 4, further comprising a spring connected between the second arm and the second member.

7. The apparatus of claim 1, wherein the adjuster is a wedge.

8. The apparatus of claim 1, further comprising a spring connected to the adjustable bracket.

9. The apparatus of claim 1, wherein the adjuster applies force between a component of the process chamber and the adjustable bracket.

10. A system for processing a substrate, comprising:
a process chamber comprising an enclosure, the enclosure having an upper portion and a lower portion defining a processing region;
a substrate support disposed in the processing region;
a plurality of lamp modules connected to the upper portion for delivering radiation to the processing region;
an adjustable bracket connected to at least one of the lamp modules; and
an adjuster connected with the adjustable bracket, the adjuster providing a force for pivoting the adjustable bracket.

11. The system of claim 10, wherein the adjuster is a micrometer.

12. The system of claim 10, wherein the adjustable bracket comprises a first member pivotably connected to a second member.

13. The system of claim 12, wherein the first member comprises a first arm and a second arm.

14. The system of claim 13, wherein the first arm is pivotably connected to the second member.

15. The system of claim 13, further comprising a spring connected to the second arm, the spring providing an opposing force to the adjuster.

16. The system of claim 10, wherein the adjuster is a wedge.

17. The system of claim 10, wherein the adjuster applies force between a component of the process chamber and the adjustable bracket for pivoting the adjustable bracket.

18. An apparatus for processing a semiconductor substrate, comprising:
a plurality of radiation modules positioned in an upper portion of a process chamber, each radiation module comprising:
a radiation source;
a base connected to the radiation source;
an adjustable bracket connected to the radiation source, the adjustable bracket comprising:
a base connected to the radiation source;
a first member comprising a first arm and a second arm, wherein the first arm is connected to the base;
a second member connected to the first member by a pivot; and
a spring connected between the second arm of the first member and the second member; and
an adjuster connected with the first member to provide a pivoting force to the first member.

19. The apparatus of claim 18, wherein the adjuster is a micrometer.

20. The apparatus of claim 18, wherein the adjuster applies force between a component of the process chamber and the adjustable bracket.
